(19) United States
(12) Patent Application Publication
(10) Pub. No.: US 2025/0385146 A1
(43) Pub. Date: Dec. 18, 2025

(54) SEMICONDUCTOR PACKAGE

(71) Applicant: SAMSUNG ELECTRONICS CO., LTD., Suwon-si (KR)

(72) Inventors: Gyumin Park, Suwon-si (KR); Hwanwook Jung, Suwon-si (KR)

(73) Assignee: SAMSUNG ELECTRONICS CO., LTD., Suwon-si (KR)

(21) Appl. No.: 19/095,699

(22) Filed: Mar. 31, 2025

(30) Foreign Application Priority Data
Jun. 13, 2024 (KR) 10-2024-0077170

(51) Int. Cl. H01L 23/13; H01L 23/00; H01L 23/31; H01L 23/538; H01L 25/00; H01L 25/18

(52) U.S. Cl. CPC H01L 23/13; H01L 23/5386; H01L 24/32; H01L 24/48; H01L 24/73; H01L 25/18; H01L 23/3107; H01L 25/50; H01L 2224/32145; H01L 2224/32225; H01L 2224/48145; H01L 2224/48227; H01L 2224/73265; H01L 2225/0651; H01L 2225/06562

(57) ABSTRACT

A semiconductor package may include: a package substrate including a first region and a second region adjacent to the first region, the package substrate further including a cavity that is recessed from an upper surface of the package substrate in the second region; a first semiconductor chip on the upper surface of the package substrate, wherein the first semiconductor chip is on the first region of the package substrate; at least one semiconductor element in the cavity of the package substrate, the at least one semiconductor element protruding above the upper surface of the package substrate; second semiconductor chips sequentially stacked on the at least one semiconductor element and overlapping with the first semiconductor chip, wherein the second semiconductor chips are connected to each other and the first semiconductor chip by adhesive films; and a molding member on the second semiconductor chips and the package substrate.

### CROSS-REFERENCE TO RELATED APPLICATION

This application claims priority under 35 U.S.C. § 119 to Korean Patent Application No. 10-2024-0077170, filed on Jun. 13, 2024 in the Korean Intellectual Property Office (KIPO), the disclosure of which is herein incorporated by reference in its entirety.

### BACKGROUND

### 1. Field

Example embodiments of the present disclosure relate to a semiconductor package and a method of manufacturing the semiconductor package. More particularly, example embodiments of the present disclosure relate to a semiconductor package including different types of chips stacked on a package substrate and a method for manufacturing the same.

### 2. Description of Related Art

In a multi-chip package (MCP), a dolmen-shaped spacer chip may be placed around a controller chip of a relatively small size, and memory chips may be stacked on the spacer chip. Here, semiconductor elements such as capacitors may be mounted on the package substrate to reduce power noise. Thus, there is a problem that a size of the package is limited due to an area occupied by the semiconductor elements.

### SUMMARY

According to example embodiments of the present disclosure, a semiconductor package having a reduced package size may be provided.

According to example embodiments of the present disclosure, a semiconductor package may be provided and include: a package substrate including a first region and a second region adjacent to the first region, the package substrate further including a cavity that extends from an upper surface of the package substrate in the second region; a first semiconductor chip on the upper surface of the package substrate, wherein the first semiconductor chip is on the first region of the package substrate; at least one semiconductor element in the cavity of the package substrate, the at least one semiconductor element protruding above the upper surface of the package substrate; a plurality of second semiconductor chips sequentially stacked on the at least one semiconductor element and overlapping with the first semiconductor chip, wherein the plurality of second semiconductor chips are connected to each other and the first semiconductor chip by adhesive films; and a molding member on the plurality of second semiconductor chips and the package substrate.

According to example embodiments of the present disclosure, a semiconductor package may be provided and include: a package substrate including a first region and a second region adjacent to the first region, the package substrate further including a cavity in the second region, in an upper surface of the package substrate; a first semiconductor chip on the upper surface of the package substrate, wherein the first semiconductor chip is on the first region of the package substrate; at least one semiconductor element in the cavity of the package substrate, the at least one semiconductor element protruding above the upper surface of the package substrate; a first adhesive film on the at least one semiconductor element and the first semiconductor chip, and in the cavity; a plurality of second semiconductor chips sequentially stacked on the first adhesive film; bonding wires electrically connecting the plurality of second semiconductor chips to the package substrate; and a molding member on the plurality of second semiconductor chips and the package substrate.

According to example embodiments of the present disclosure, a semiconductor package may be provided and include: a package substrate including a third region and a fourth region spaced apart from the third region, the third region including a first region and a second region, and the package substrate further including a cavity in the second region, in an upper surface of the package substrate; a first semiconductor chip on the first region, on the upper surface of the package substrate; at least one semiconductor element in the cavity, the at least one semiconductor element protruding from the upper surface of the package substrate; a plurality of second semiconductor chips on the third region, on the upper surface of the package substrate, and sequentially stacked on the at least one semiconductor element, wherein the plurality of second semiconductor chips are connected to each other and the first semiconductor chip by first adhesive films; a spacer chip on the fourth region, on the upper surface of the package substrate; a plurality of third semiconductor chips sequentially stacked on the spacer chip, wherein the plurality of third semiconductor chips are connected to each other and the spacer chip by second adhesive films; a plurality of fourth semiconductor chips sequentially stacked on the plurality of second semiconductor chips and the plurality of third semiconductor chips, wherein the plurality of fourth semiconductor chips are connected to each other and the plurality of second semiconductor chips and the plurality of third semiconductor chips by third adhesive films; and a molding member on the plurality of second semiconductor chips, the plurality of third semiconductor chips, the plurality of fourth semiconductor chips, and the package substrate.

A plurality of semiconductor elements may be disposed within the cavity of the package substrate to protrude from the package substrate by a predetermined height. The plurality of second semiconductor chips may be supported and mounted on the package substrate by the plurality of semiconductor elements.

The plurality of semiconductor elements for reducing power noise may replace a role of a conventional spacer chip. Accordingly, costs for the spacer chip may be reduced, to thereby improve productivity, and a mounting area of the semiconductor elements may be reduced, to thereby reduce a package size.

### BRIEF DESCRIPTION OF DRAWINGS

Example embodiments will be more clearly understood from the following detailed description taken in conjunction with the accompanying drawings.

FIGS. 1 to 26 represent non-limiting example embodiments as described herein.

FIG. 1 is a plan view illustrating a semiconductor package in accordance with example embodiments.

FIG. 2 is a cross-sectional view taken along the line A1-A1′ in FIG. 1.

FIG. 3 is a cross-sectional view taken along the line B1-B1′ in FIG. 1.

FIG. 4 is an enlarged cross-sectional view illustrating a portion C1 in FIG. 2.

FIGS. 5 to 25 are views illustrating a method of manufacturing a semiconductor package in accordance with example embodiments.

FIG. 26 is an enlarged cross-sectional view illustrating a portion of a semiconductor package in accordance with example embodiments.

### DETAILED DESCRIPTION

Hereinafter, non-limiting example embodiments will be explained in detail with reference to the accompanying drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

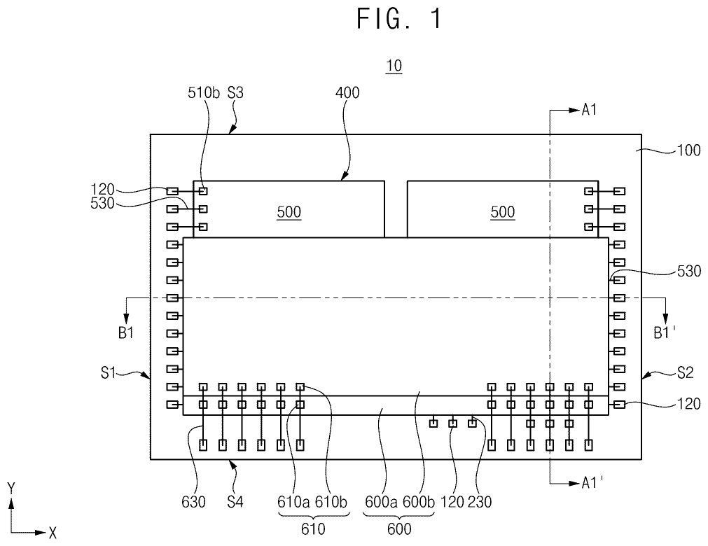

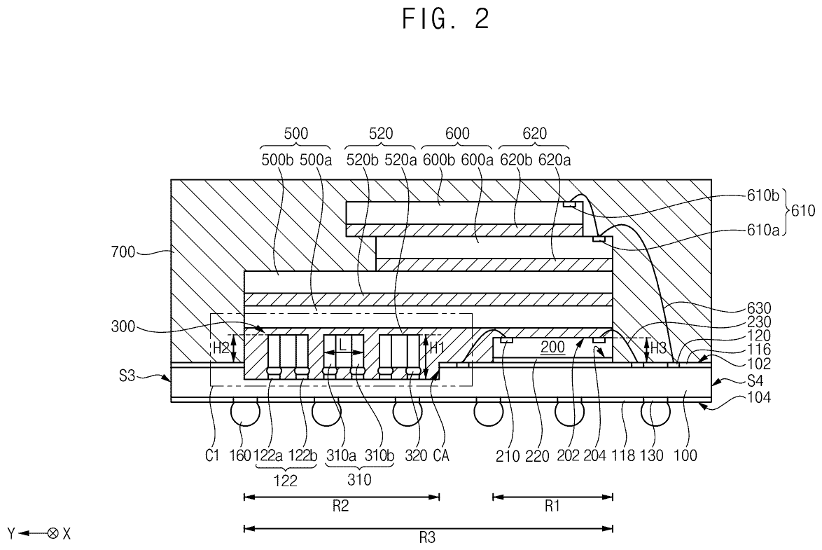

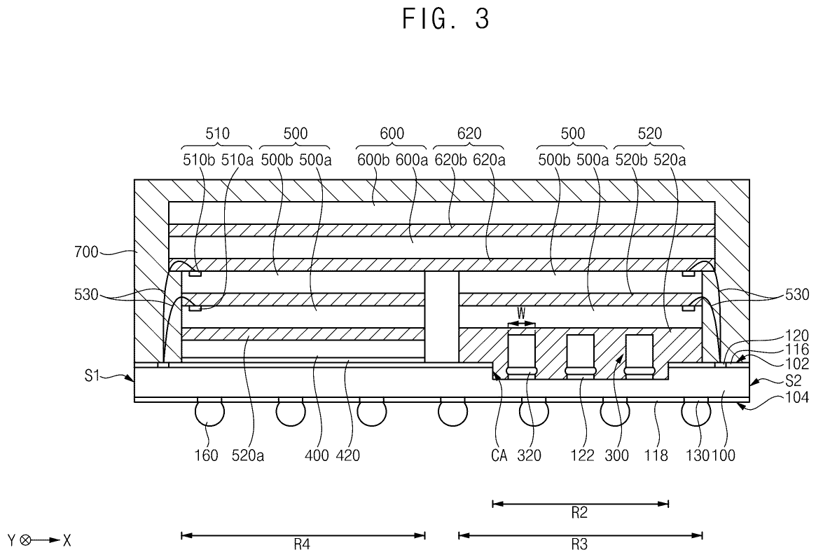

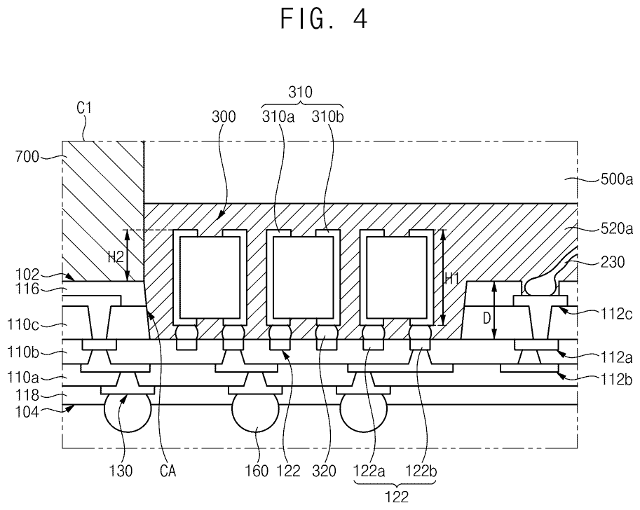

FIG. 1 is a plan view illustrating a semiconductor package in accordance with example embodiments. FIG. 2 is a cross-sectional view taken along the line A1-A1′ in FIG. 1. FIG. 3 is a cross-sectional view taken along the line B1-B1′ in FIG. 1. FIG. 4 is an enlarged cross-sectional view illustrating a portion C1 in FIG. 2. FIG. 1 is a plan view illustrating the semiconductor package, wherein a molding member in FIGS. 2 and 3 is omitted.

Referring to FIGS. 1 to 4, a semiconductor package 10 may include a package substrate 100, a first semiconductor chip 200, at least one semiconductor element 300, a plurality of second semiconductor chips 500, and a molding member 700. The semiconductor package 10 may further include a spacer chip 400 and a plurality of third semiconductor chips 600. The semiconductor package 10 may further include conductive connection members (e.g., bonding wires 230, bonding wires 530, and bonding wires 630) that electrically connect the first semiconductor chip 200, the plurality of second semiconductor chips 500, and the plurality of third semiconductor chips 600 to the package substrate 100. Further, the semiconductor package 10 may include external connection members 160.

In addition, the semiconductor package 10 may be a multi-chip package (MCP) including different types of semiconductor chips. The semiconductor package 10 may be a System In Package (SIP) including a plurality of semiconductor chips stacked or arranged in one package to perform all or most of the functions of an electronic system.

In example embodiments, the package substrate 100 may be a substrate having an upper surface 102 and a lower surface 104 opposite to each other. For example, the package substrate 100 may include a coreless substrate. Alternatively, the package substrate 100 may include a printed circuit board (PCB), such as a core multilayer substrate. The printed circuit board may be a multilayer circuit board having vias and various circuits therein. The package substrate 100 may include internal wirings as channels for electrical connection with the first semiconductor chip 200, the second semiconductor chips 500, and the third semiconductor chips 600.

The package substrate 100 may include a first side portion S1 and a second side portion S2 extending in a direction parallel to a second direction (Y direction) and facing away from each other, and a third side portion S3 and a fourth side portion S4 extending in a direction parallel to a first direction (X direction) perpendicular to the second direction and facing away from each other.

The package substrate 100 may have a first region R1 in which the first semiconductor chip 200 is mounted and a second region R2 adjacent to and spaced apart from the first region R1. The package substrate 100 may further include a third region R3 including the first region R1 and the second region R2. The package substrate 100 may further include a fourth region R4 spaced apart from the third region R3. The third region R3 may be adjacent to the second side portion S2, and the fourth region R4 may be adjacent to the first side portion S1. The plurality of second semiconductor chips 500 may be respectively arranged on the third region R3 and the fourth region R4.

A plurality of substrate pads 120 may be arranged on the upper surface 102 of the package substrate 100. Among the plurality of substrate pads 120, first pads may be arranged along an edge region of the first region R1 outside the first region R1. Among the plurality of substrate pads 120, second pads may be arranged along the first side portion S1 and the second side portion S2 of the package substrate 100. Among the plurality of substrate pads 120, third pads may be arranged along the fourth side portion S4 of the package substrate 100. As described below, the first pads may be electrically connected to the first semiconductor chip 200 by conductive connection members such as bonding wires 230, the second pads may be electrically connected to the plurality of second semiconductor chips 500 by conductive connection members such as bonding wires 530, and the third pads may be electrically connected to the plurality of third semiconductor chips 600 by conductive connection members such as bonding wires 630.

The substrate pads 120 may be respectively connected to wirings. The wirings may extend from the upper surface 102 or within the package substrate 100. For example, at least a portion of the wiring may be used as a landing pad for the substrate pad. Although only a few substrate pads are illustrated in the figures, it will be understood that the number, shape, and arrangement of the substrate pads are provided by way of example, and embodiments of the present disclosure are not limited thereto.

As illustrated in FIG. 4, in example embodiments, the package substrate 100 may be a coreless substrate formed by an embedded trace substrate (ETS) method. For example, the package substrate 100 may include a plurality of insulating layers (e.g., a core layer 110a, an upper insulating layer 110b, and a lower insulating layer 110c) and circuit layers (e.g., a circuit layer 112a, a lowermost circuit layer 112b, and an uppermost circuit layer 112c) in the insulating layers. Protective layers (e.g., an upper protective layer 116 and a lower protective layer 118) such as solder resist layers may be formed on outermost surfaces of the circuit layers. The upper protective layer 116 may cover the entire upper surface of the insulating layers except for the substrate pads 120. The lower protective layer 118 may cover the entire lower surface of the insulating layers except for lower substrate pads 130.

Each of the circuit layers may include a wiring pattern. Each of the wiring patterns may include a pads, a trace, a via, etc. An upper surface of the upper protective layer 116 may define the upper surface 102 of the package substrate 100, and a lower surface of the lower protective layer 118 may define the lower surface 104 of the package substrate 100. At least a portion of the pad of the uppermost circuit layer 112c may be provided as the substrate pad 120, and at least a portion of the pad of the lowermost circuit layer 112b may be provided as the lower substrate pad 130. It will be understood that the coreless substrate used as the package substrate is provided as an example, and embodiments of the present disclosure are not limited thereto.

In example embodiments, a cavity CA may be provided to have a predetermined depth D from the upper surface 102 of the second region R2 of the package substrate 100. For example, the cavity CA may be formed by a laser drilling process. The cavity CA may have a predetermined depth D from the upper surface 102 of the package substrate 100 and may expose portions (e.g., pad portions such as second substrate pads 122) of the circuit layer 112a within the second region R2. The exposed pad portions may be provided as second substrate pads 122. As described below, the semiconductor element 300, such as a capacitor, may be mounted on the second substrate pads 122. The predetermined depth D of the cavity CA may be within a range of 100 μm to 200 μm from the upper surface 102 of the package substrate 100. The predetermined depth D of the cavity CA may be determined in consideration of a height H1 of the semiconductor element 300 mounted in the cavity CA, a height H3 of the first semiconductor chip 200, etc.

A plurality of second substrate pads 122 may be arranged in an array form at (e.g., in or on) a bottom surface of the cavity CA. The plurality of second substrate pads 122 may be provided to mount several to several tens of the semiconductor elements 300.

In example embodiments, the first semiconductor chip 200 may be disposed on the first region R1 of the package substrate 100. The first semiconductor chip 200 may be placed so as to overlap at least a portion of the first region R1 of the package substrate 100. The first semiconductor chip 200 may be mounted on the package substrate 100 by a wire bonding method. The first semiconductor chip 200 may be attached to the upper surface 102 of the package substrate 100 by an adhesive film 220. The first semiconductor chip 200 may be arranged such that a backside surface of the first semiconductor chip 200, opposite to a front surface (e.g., an active surface) of the first semiconductor chip 200 at (e.g., in or on) which the first chip pads 210 are formed, faces the package substrate 100. The first semiconductor chip 200 may have a rectangular shape having four sides when viewed in plan view.

The first semiconductor chip 200 may be a logic chip including a logic circuit. The logic chip may be a controller that controls memory chips. The first semiconductor chip may be a processor chip such as an application-specific integrated circuit (ASIC) or an application processor (AP) as a host such as a central processing unit (CPU), graphics processing unit (GPU), or system on chip (SOC).

The first chip pads 210 of the first semiconductor chip 200 may be electrically connected to the first pads among the substrate pads 120 at (e.g., in or on) the upper surface 102 of the package substrate 100 by the bonding wires 230.

Alternatively, the first semiconductor chip 200 may be mounted on the package substrate 100 by a flip chip bonding method. In this case, among the substrate pads 120, the first pads are arranged in an array form within the first region R1, and the first chip pads 210 of the first semiconductor chip 200 may be electrically connected to the first pads among the substrate pads 120 of the package substrate 100 by conductive bumps such as, for example, solder bumps.

For example, a thickness of the first semiconductor chip 200 may be within a range of 90 μm to 150 μm. The height (H1) of the first semiconductor chip 200 from the upper surface 102 of the package substrate 100 may be within a range of 125 μm to 200 μm.

In example embodiments, at least one semiconductor element 300 may be disposed within the cavity CA of the package substrate 100. The semiconductor element 300 may be electrically connected to the first semiconductor chip 200 to remove electrical noises and ensure that power is supplied uniformly. A plurality of semiconductor elements 300 may be placed within the cavity CA. For example, the number of semiconductor elements 300 may be within a range of 6 to 15.

For example, the semiconductor element 300 may include a passive device, a multi-layer ceramic capacitor (MLCC), a low inductance chip capacitor (LICC), a die side capacitor (DSC), a land side capacitor (LSC), an inductor, an integrated passive device (IPD), etc.

As illustrated in FIG. 4, the plurality of semiconductor elements 300 may be mounted on the second substrate pads 122 of the package substrate 100 via conductive bumps 320. The conductive bumps 320 may be bonded to first external terminal 310a and the second external terminal 310b of the semiconductor element 300 and a pair of bonding pads (e.g., the first bonding pad 122a and the second bonding pad 122b) of the second substrate pads 122. Accordingly, the first external terminal 310a and the second external terminal 310b of each of the semiconductor elements 300 may be electrically connected to the second substrate pads 122 of the package substrate 100, that is, the pair of bonding pads (e.g., the first bonding pad 122a and the second bonding pad 122b), by the conductive bumps 320 as conductive connection members.

A length of the semiconductor element 300 in the first direction (X direction), that is, a width W may be within a range of 100 μm to 250 μm. A length L of the semiconductor element 300 in the second direction (Y direction) may be within a range of 200 μm to 600 μm. The height H1 of the semiconductor element 300 may be within a range of 250 μm to 400 μm. The semiconductor element 300 may protrude from the package substrate 100 by a height H3, which may be predetermined. The semiconductor elements 300 may protrude from the package substrate 100 to be support spacers that support at least a portion of the second semiconductor chip. The height H3 of the semiconductor element 300 protruding from the package substrate 100 may be determined in consideration of the height H1 of the first semiconductor chip 200 from the package substrate 100. The height H3 of the semiconductor element 300 protruding from the package substrate 100 may be equal to or greater than the height H1 of the first semiconductor chip 200 from the package substrate 100.

In example embodiments, the plurality of second semiconductor chips 500 may be supported and mounted on the third region R3 of the package substrate 100 by the plurality of semiconductor elements 300. The plurality of second semiconductor chips 500 may be arranged to overlap at least a portion of the third region R3 of the package substrate 100. The plurality of second semiconductor chips 500 may be attached onto the at least one semiconductor element 300 using adhesive films 520. Among the plurality of second semiconductor chips, a lowermost second semiconductor chip 500a may be attached onto the plurality of semiconductor elements 300 using a first adhesive film 520a. Among the plurality of second semiconductor chips, a remaining chip (e.g., the second semiconductor chip 500b) may be sequentially attached onto the lowermost second semiconductor chip 500a using a second adhesive film 520b.

The second semiconductor chips 500 may include a memory chip including a memory circuit. For example, the second semiconductor chips 500 may include volatile memory devices such as static random-access memory (SRAM) devices, dynamic random-access memory (DRAM) devices, etc., and non-volatile memory devices such as flash memory devices, phase-change random-access memory (PRAM) devices, magnetoresistive random-access memory (MRAM) devices, resistive random-access memory (ReRAM) devices, etc. In this embodiment, the second semiconductor chips 500 may include DRAM devices.

The lowermost second semiconductor chip 500a may be attached onto the plurality of semiconductor elements 300 and the first semiconductor chip 200 by using the first adhesive film 520a such as a die attach film (DAF) by a die attach process.

The lowermost second semiconductor chip 500a may be arranged such that a backside surface (e.g., an inactive surface), opposite to a front surface where second chip pads 510a are formed, faces the package substrate 100. The lowermost second semiconductor chip 500a may have a rectangular shape with four sides when viewed in a plan view.

For example, the first adhesive film 520a may be attached onto the backside surface of the lowermost second semiconductor chip 500a, and the lowermost second semiconductor chip 500a to which the first adhesive film 520a is attached may be attached onto the plurality of semiconductor elements 300 and the first semiconductor chip 200 by a thermal compression process. The lowermost second semiconductor chip 500a may be pressed onto the plurality of semiconductor elements 300 by a die attaching tool and heated to a high temperature by a heater block within a support system that supports the package substrate 100.

A portion of the DAF having fluidity due to the pressure and temperature may flow into a space between the first semiconductor chip 200 and the plurality of semiconductor elements 300 and fill the inside of the cavity CA. A portion of the DAF within the cavity CA may fill a space between the semiconductor elements 300 and sidewalls of the cavity CA and a space between the semiconductor elements 300 and the bottom surface of the cavity CA.

The remaining chip (e.g., second semiconductor chip 500b) among the plurality of second semiconductor chips 500 may be sequentially attached to the lowermost second semiconductor chip 500a by a second adhesive film 520b. The second semiconductor chip 500b may be sequentially attached to the lowermost second semiconductor chip 500a using the second adhesive film 520b such as a die attach film (DAF) by a die attach process. A thickness of the second adhesive film 520b may be less than a thickness of the first adhesive film 520a. The thickness of the second adhesive film 520b may be within a range of 10 μm to 20 μm.

A planar area of the second semiconductor chip (e.g., one second semiconductor chip 500) may be greater than a planar area of the first semiconductor chip 200. The plurality of second semiconductor chips 500 may be aligned to overlap each other. Alternatively, the plurality of second semiconductor chips 500 may be sequentially offset aligned from each other.

It will be understood that the number, size, arrangement, etc., of the second semiconductor chips 500 are provided as examples, and embodiments of the present disclosure are not limited thereto. Additionally, although only a few second chip pads 510a are illustrated in the figures, it will be understood that the structure, shapes and arrangements of the second chip pads 510a are provided by way of example and that embodiments of the present disclosure are not limited thereto.

The second semiconductor chips 500 may be electrically connected to the package substrate 100 by conductive connection members (e.g., bonding wires 530). Specifically, the second chip pads 510 of the second semiconductor chips 500 may be electrically connected to the substrate pads 120 on the upper surface 102 of the package substrate 100 by the bonding wires 530.

In example embodiments, the plurality of second semiconductor chips 500 may be mounted on the fourth region R4 of the package substrate 100 while being supported by a spacer chip 400. The plurality of second semiconductor chips 500a, 500b may be arranged to overlap at least a portion of the fourth region R4 of the package substrate 100.

The spacer chip 400 may be placed on the fourth region R4 spaced apart from the third region R3. The spacer chip 400 may be formed by cutting a silicon wafer (W) by a sawing process, and then attached to the upper surface 102 of the package substrate 100 using an adhesive film by a die attach process. A height of the spacer chip 400 from the package substrate 100 may be the same as or similar to the height H3 of the first semiconductor chip 200.

The plurality of second semiconductor chips 500 may be attached to the spacer chip 400 using the adhesive films 520. The lowermost second semiconductor chip 500a among the plurality of second semiconductor chips 500 may be attached to the spacer chip 400 using the first adhesive film 520a. The planar area of the lowermost second semiconductor chip 500a may be the same as or similar to a planar area of the spacer chip 400. The remaining chip (e.g., the second semiconductor chip 500b) among the plurality of second semiconductor chips 500 may be sequentially attached on the lowermost second semiconductor chip 500a using the second adhesive film 520b.

The second semiconductor chips 500 may be electrically connected to the package substrate 100 by the conductive connection members (e.g., bonding wires 530). Specifically, the second chip pads 510 of the second semiconductor chips 500 may be electrically connected to the substrate pads 120 at (e.g., in or on) the upper surface 102 of the package substrate 100 by the bonding wires 530.

In example embodiments, the plurality of third semiconductor chips 600 may be attached on the plurality of second semiconductor chips 500 using adhesive films 620. The plurality of third semiconductor chips 600 may be arranged to overlap at least a portion of the third region R3 and at least a portion of the fourth region R4 of the package substrate 100.

In example embodiments, a lowermost third semiconductor chip 600a may be attached onto the plurality of second semiconductor chips 500 using a third adhesive film 620a. The lowermost third semiconductor chip 600a may be attached onto the plurality of second semiconductor chips 500 using a third adhesive film 620a, such as a die attach film (DAF), by a die attach process. The lowermost third semiconductor chip 600a may be disposed on the plurality of second semiconductor chips 500 on the third region R3 and the plurality of second semiconductor chips 500 on the fourth region R4. The lowermost third semiconductor chip 600a may have a rectangular shape extending in the first direction (X direction) to cover the third region R3 and the fourth region R4 that are spaced apart from each other. The lowermost third semiconductor chip 600a may be arranged such that a backside surface (e.g., an inactive surface), which is opposite to a front surface at (e.g., in or on) which third chip pads 610a are formed, faces the package substrate 100.

A remaining chip (e.g., a third semiconductor chip 600b) among the plurality of third semiconductor chips 600 may be sequentially attached onto the lowermost third semiconductor chip 600a using a fourth adhesive film 620b. The third semiconductor chip 600b may be sequentially attached onto the lowermost third semiconductor chip 600a using the fourth adhesive film 620b, such as a die attach film (DAF), by a die attach process.

The plurality of third semiconductor chips 600 may be sequentially offset aligned. For example, the third semiconductor chips 600 may be stacked in a cascade structure. The third semiconductor chips 600 may be sequentially aligned with an offset in a third side direction (Y direction) of the package substrate 100. Alternatively, the plurality of third semiconductor chips 600 may be aligned to overlap each other.

The third semiconductor chips 600 may include a memory chip including a memory circuit. For example, the third semiconductor chips 600 may include volatile memory devices such as SRAM devices, DRAM devices, and non-volatile memory devices such as flash memory devices, PRAM devices, MRAM devices, ReRAM devices, etc. In this embodiment, the third semiconductor chips 600 may include VNAND devices.

The third semiconductor chips 600 may be electrically connected to the package substrate 100 by conductive connection members (e.g., the bonding wires 630). Specifically, third chip pads 610 of the third semiconductor chips 600 may be electrically connected to the substrate pads 120 at (e.g., in or on) the upper surface 102 of the package substrate 100 by bonding wires 630.

In example embodiments, the molding member 700 may cover the first semiconductor chip 200, the second semiconductor chips 500, the third semiconductor chips, and the bonding wires 230, 530, 630 on the upper surface 102 of the package substrate 100. The molding member may include a thermosetting resin such as, for example, an epoxy mold compound (EMC).

In example embodiments, the lower substrate pads 130 for providing electrical signals may be formed at (e.g., in or on) the lower surface 104 of the package substrate 100. The lower substrate pads 130 may be exposed by the lower protective layer 118. An external connection member 160 for electrical connection with an external device may be arranged on the lower substrate pad 130 of the package substrate 100. For example, the external connection member 160 may be a solder ball. The semiconductor package 10 may be mounted on a module substrate via the solder balls to form a memory module.

As mentioned above, the semiconductor package 10 may include the first semiconductor chip 200 disposed on the upper surface 102 of the package substrate 100, the at least one semiconductor element 300 disposed within the cavity CA having the predetermined depth D from the upper surface 102 of the package substrate 100, and the plurality of second semiconductor chips 500 disposed on the at least one semiconductor element 300 to cover the first semiconductor chip 200.

The plurality of semiconductor elements 300 may be disposed within the cavity CA of the package substrate 100 to protrude from the package substrate 100 by the predetermined height H3. The plurality of second semiconductor chips 500 may be supported and mounted on the third region R3 of the package substrate 100 by the plurality of semiconductor elements 300.

The plurality of semiconductor elements 300 for reducing power noise may replace a role of a conventional spacer chip. Accordingly, costs for the spacer chip may be reduced, to thereby improve productivity, and a mounting area of the semiconductor elements may be reduced, to thereby reduce a package size.

Hereinafter, a method of manufacturing the semiconductor package of FIG. 1 will be described.

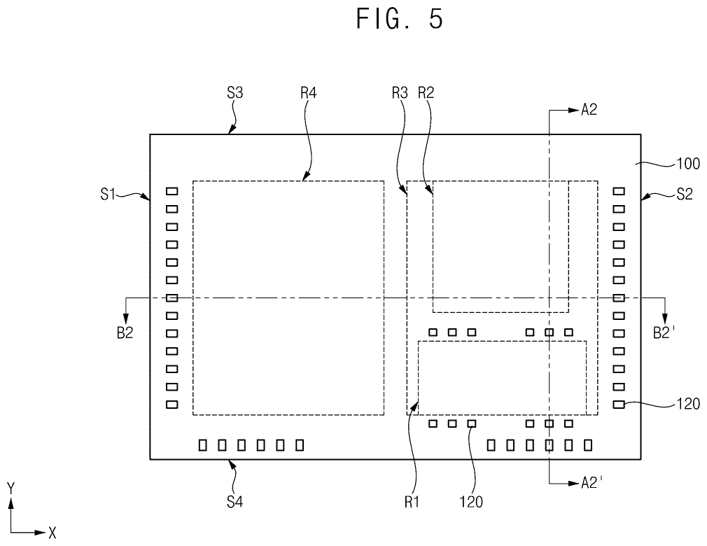

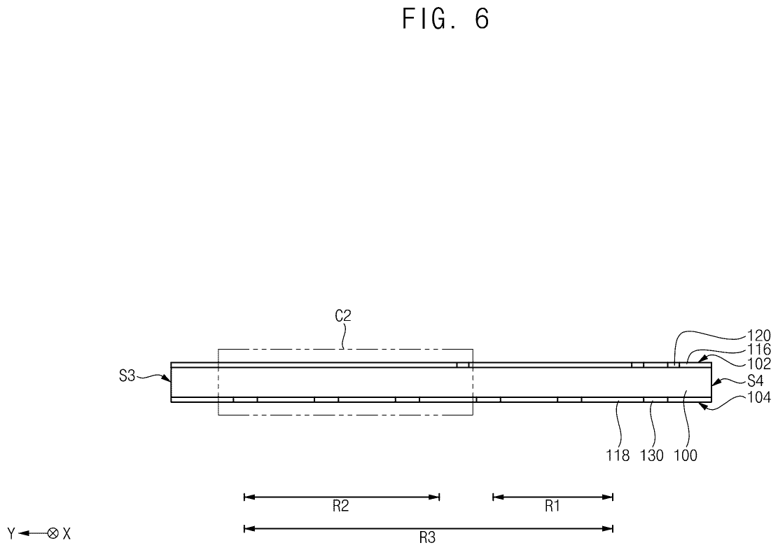

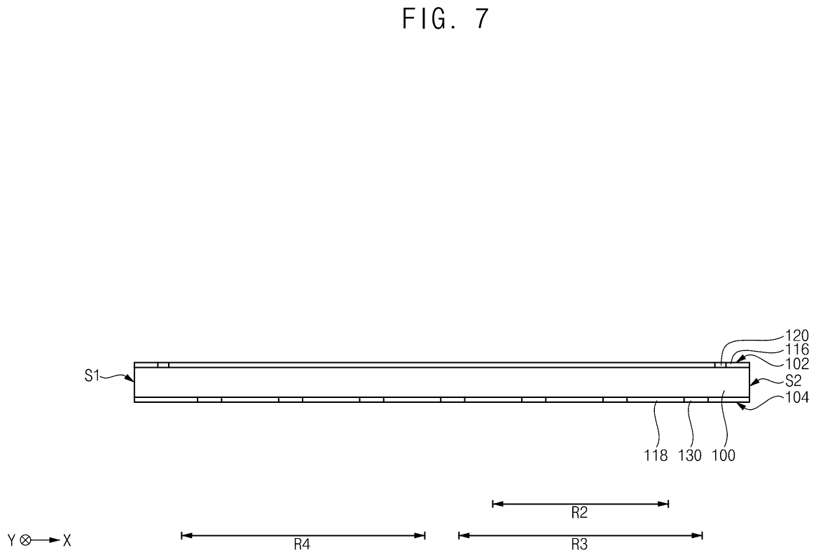

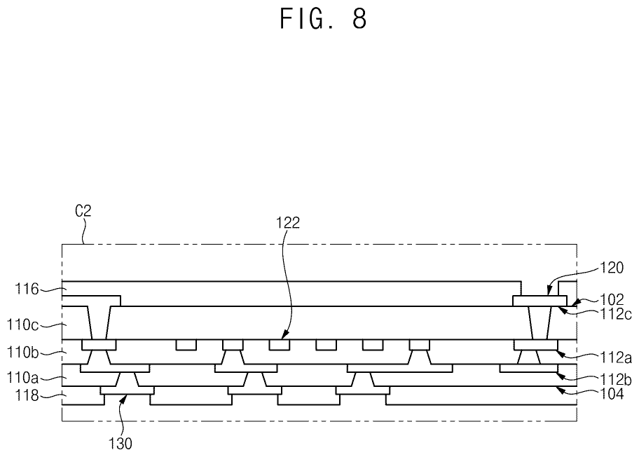

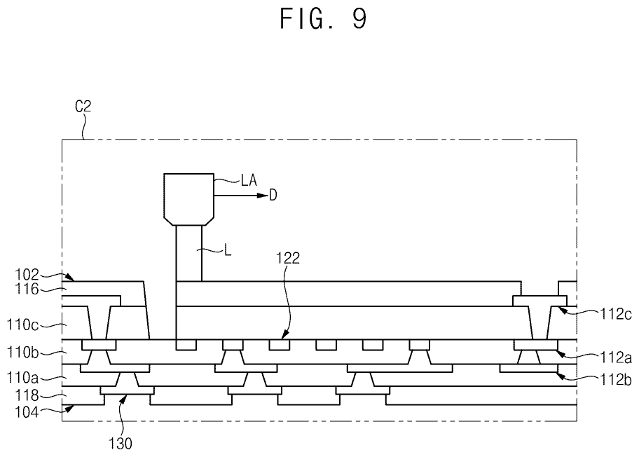

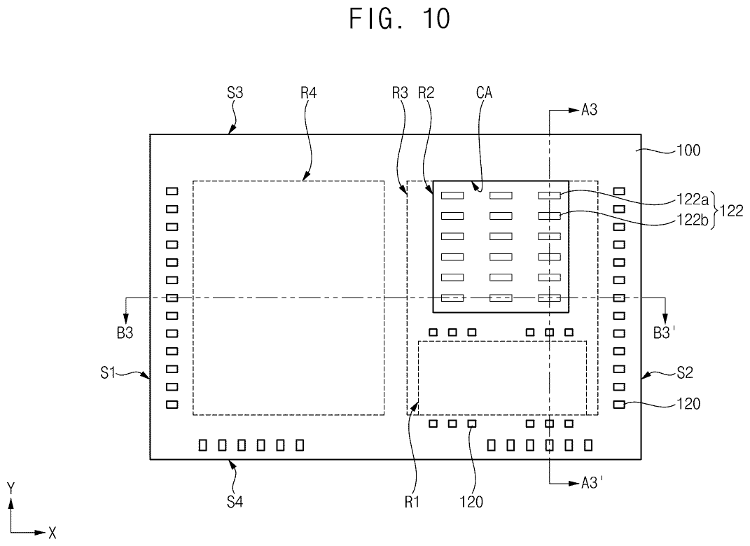

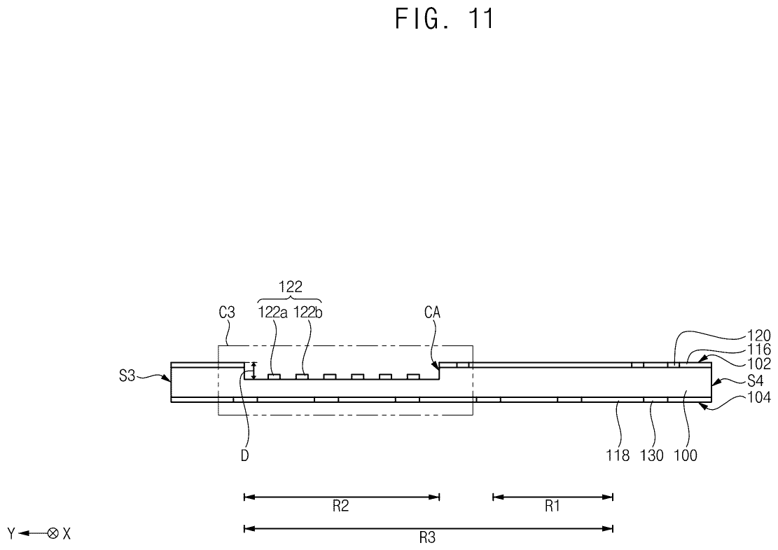

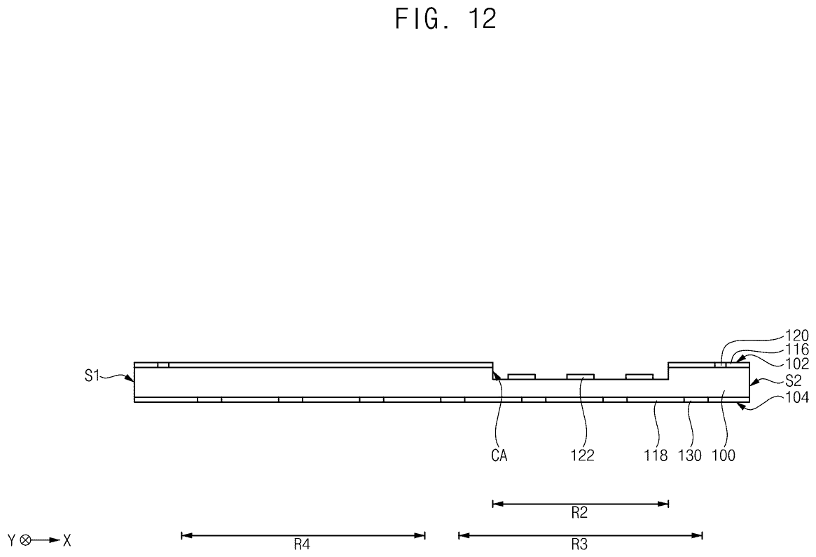

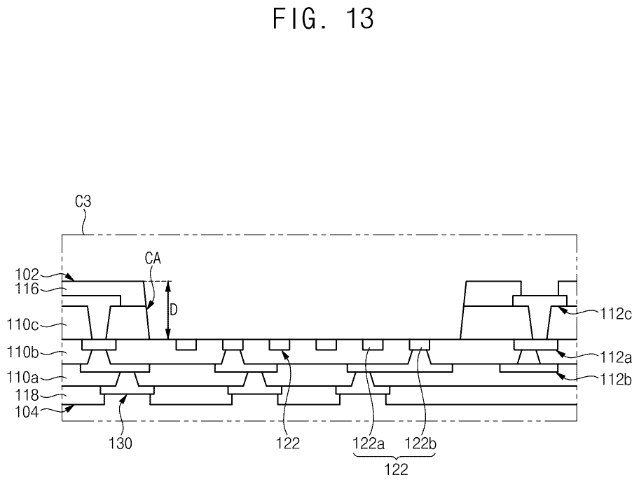

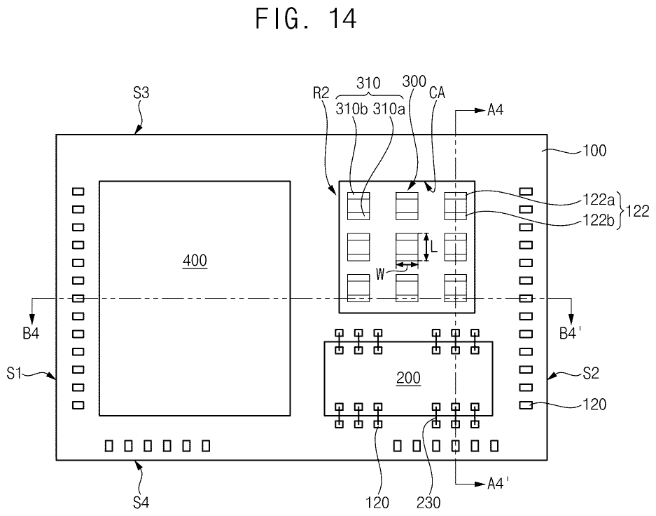

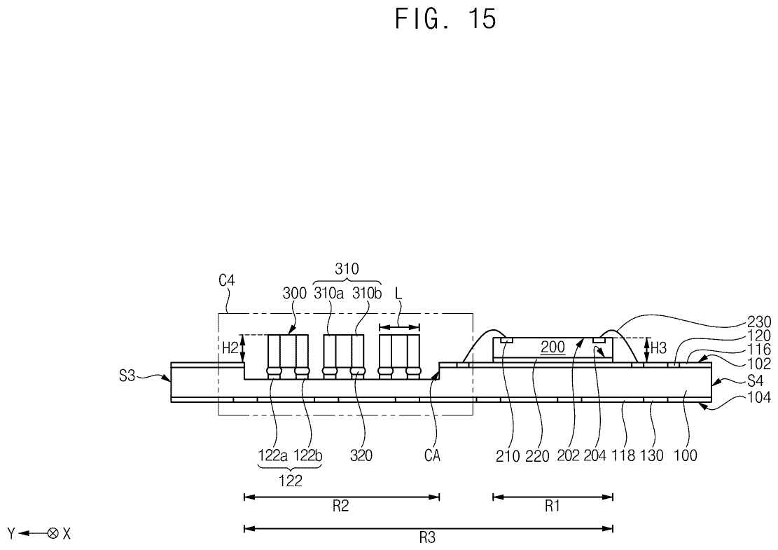

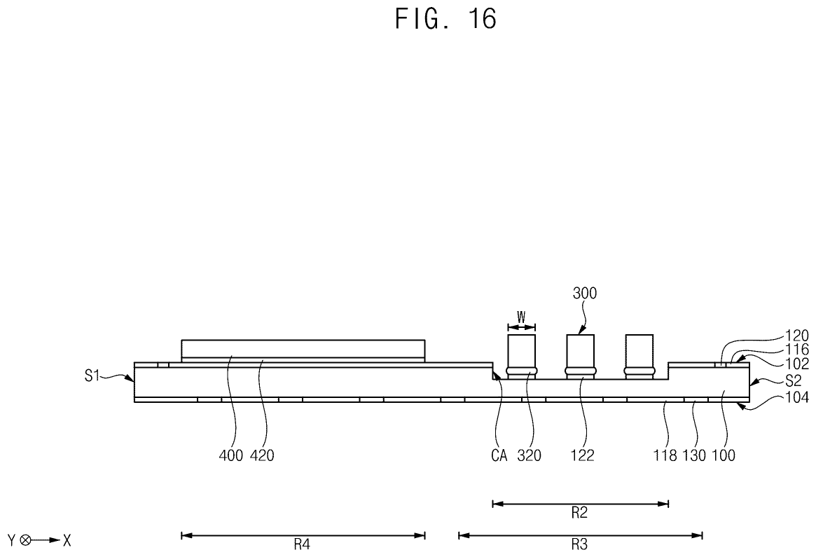

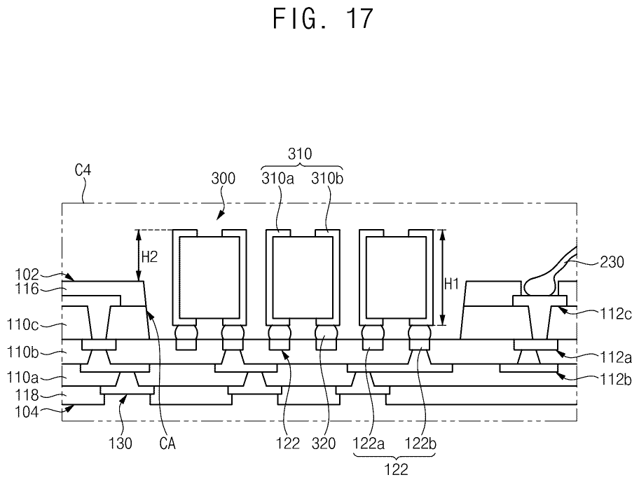

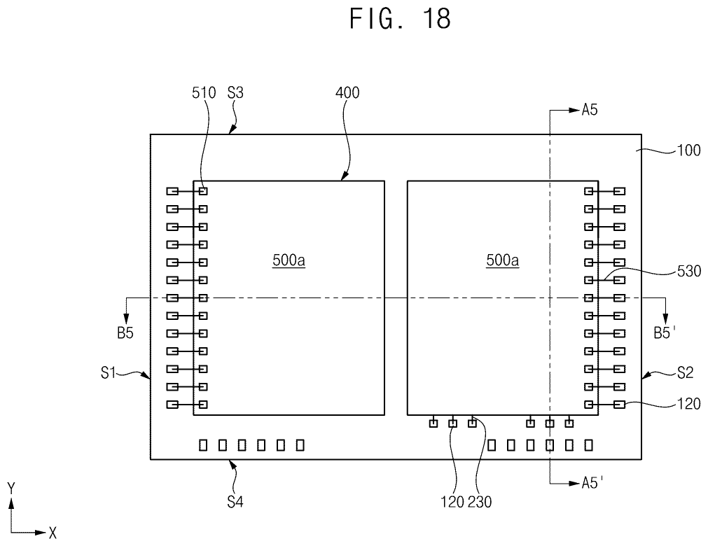

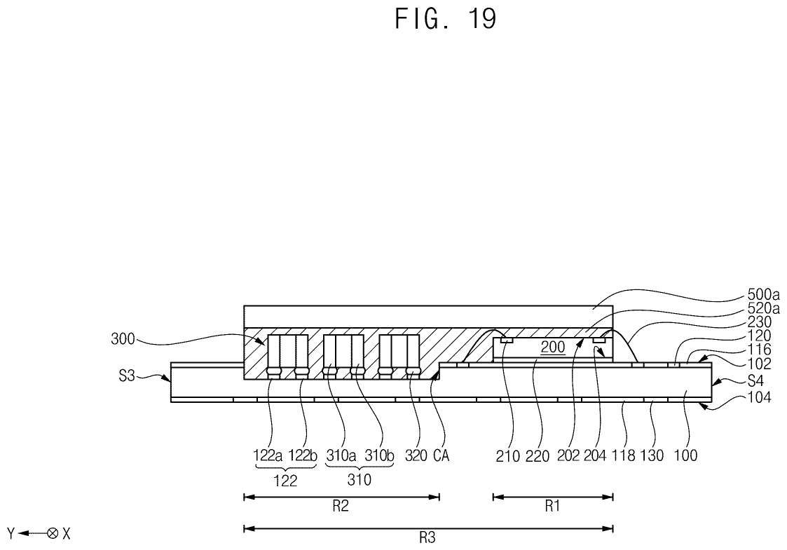

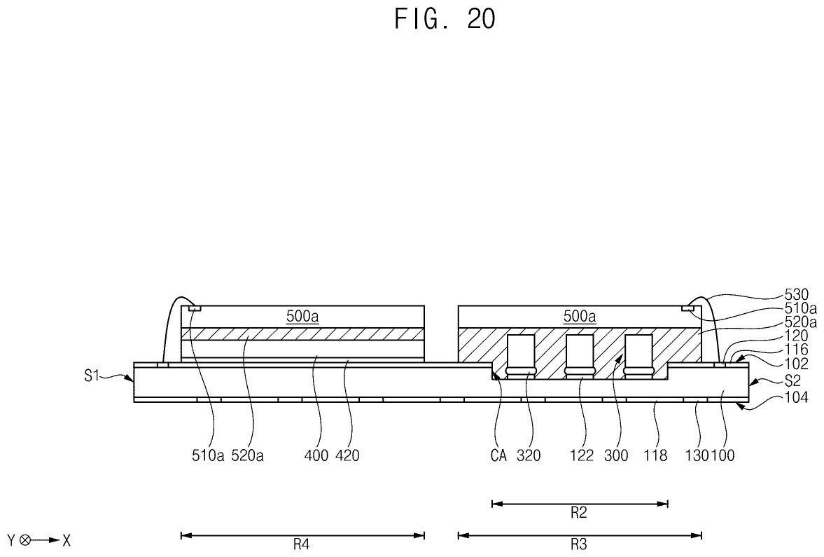

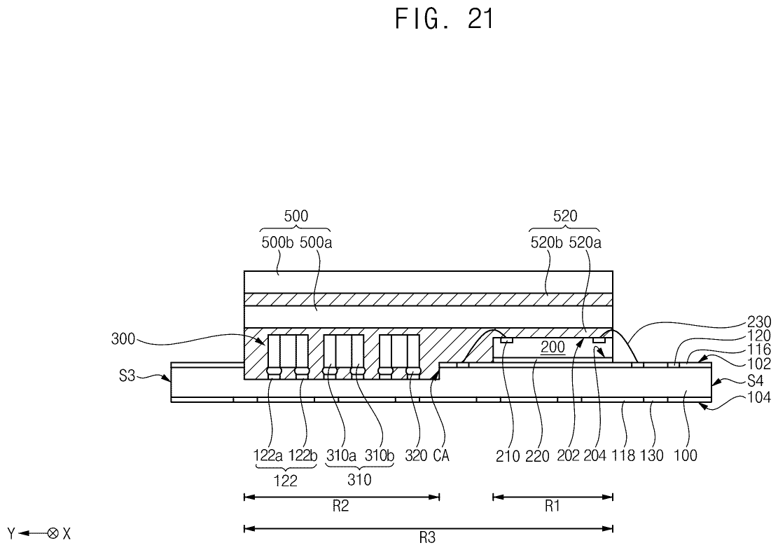

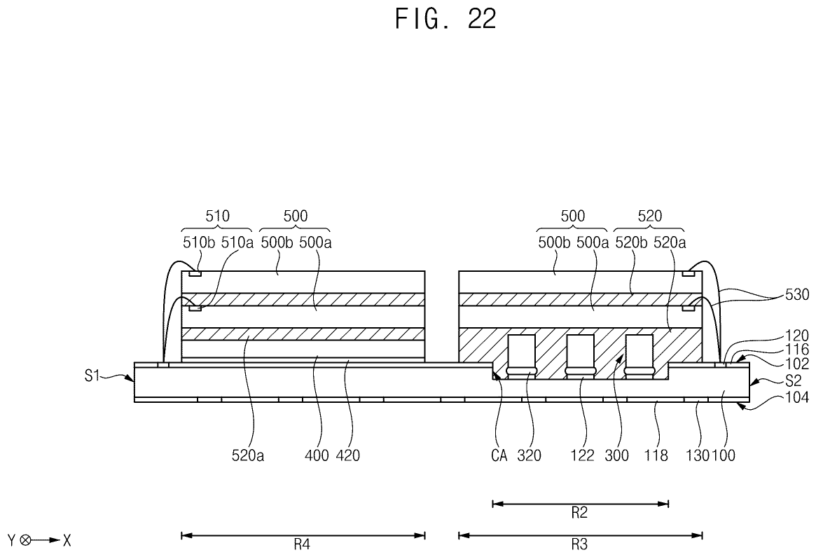

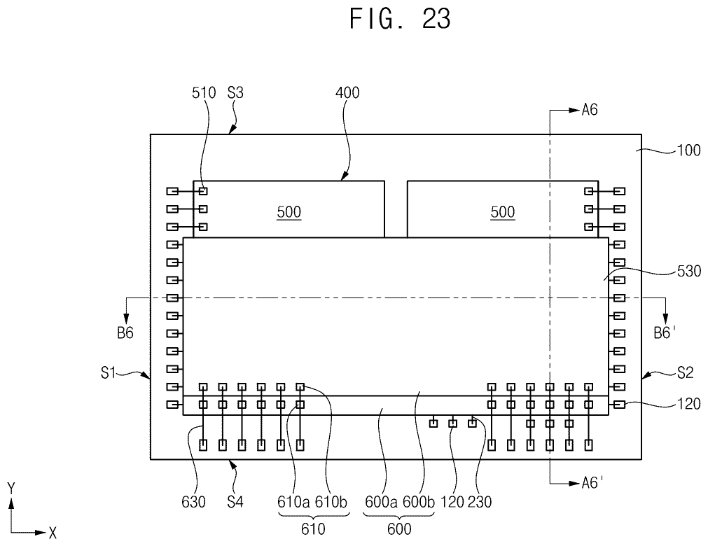

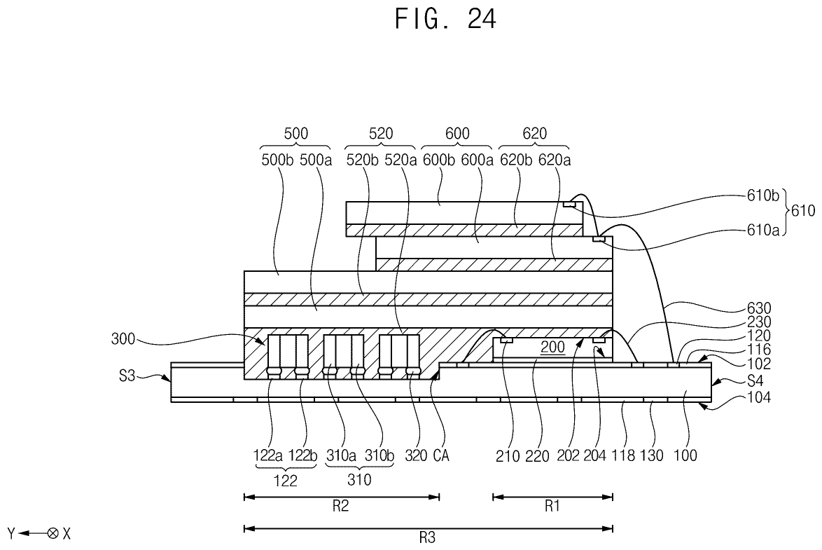

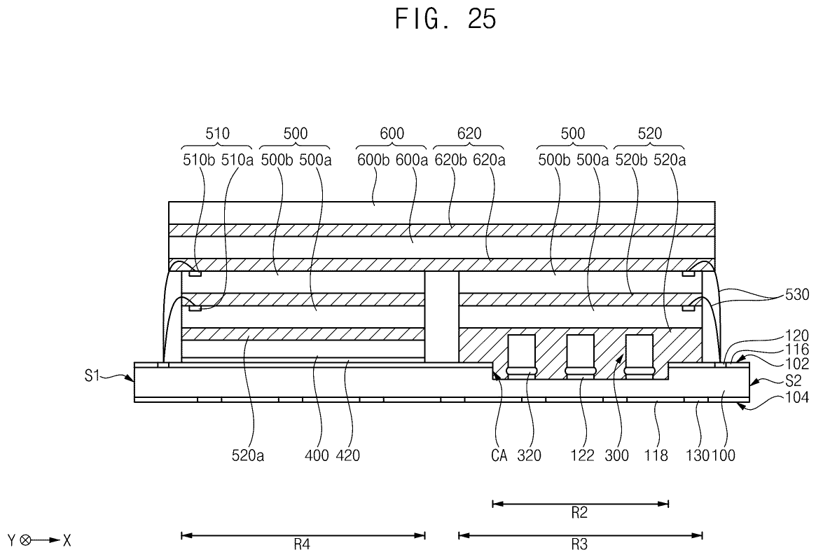

FIGS. 5 to 25 are views illustrating a method of manufacturing a semiconductor package in accordance with example embodiments. FIGS. 5, 10, 14, 18, and 23 are plan views illustrating a method of manufacturing a semiconductor package in accordance with example embodiments. FIG. 6 is a cross-sectional view taken along a line A2-A2′ in FIG. 5. FIG. 7 is a cross-sectional view taken along a line B2-B2′ in FIG. 5. FIGS. 8 and 9 are enlarged cross-sectional views illustrating a portion C2 in FIG. 6. FIG. 11 is a cross-sectional view taken along a line A3-A3′ in FIG. 10. FIG. 12 is a cross-sectional view taken along a line B3-B3′ in FIG. 10. FIG. 13 is an enlarged cross-sectional view illustrating a portion C3 in FIG. 11. FIG. 15 is a cross-sectional view taken along a line A4-A4′ in FIG. 14. FIG. 16 is a cross-sectional view taken along a line B4-B4′ in FIG. 14. FIG. 17 is an enlarged cross-sectional view illustrating a portion C4 in FIG. 15. FIGS. 19 and 21 are cross-sectional views taken along a line A5-A5′ in FIG. 18. FIGS. 20 and 22 are cross-sectional views taken along a line B5-B5′ in FIG. 18. FIG. 24 is a cross-sectional view taken along a line A6-A6′ in FIG. 23. FIG. 25 is a cross-sectional view taken along a line B6-B6′ in FIG. 23.

Referring to FIGS. 5 to 13, a package substrate 100 having at least one cavity CA may be provided.

As illustrated in FIGS. 5 to 8, the package substrate 100 having an upper surface 102 and a lower surface 104 opposite to the upper surface 102 may be provided. The package substrate 100 may include internal wirings as channels for electrical connection with a first semiconductor chip, second semiconductor chips, and third semiconductor chips as described below.

The package substrate 100 may include a first side portion S1 and a second side portion S2 that extend in a direction parallel to a second direction (Y direction) and face away from each other, and a third side portion S3 and a fourth side portion S4 that extend in a direction parallel to a first direction (X direction) that is perpendicular to the second direction and face away from each other.

The package substrate 100 may have a first region R1 in which the first semiconductor chip is mounted. As described below, the first region R1 may be a region in which the first semiconductor chip as a controller chip is mounted. The first region R1 may have a rectangular shape when viewed in a plan view. The package substrate 100 may have a second region R2 adjacent to and spaced from the first region R1. The first region R1 may be adjacent to the fourth side portion S4, and the second region R2 may be adjacent to the third side portion S3. As described below, the cavity having a predetermined depth may be formed from the upper surface 102 in the second region R2, and semiconductor elements may be mounted in the cavity.

The package substrate 100 may further include a third region R3 including the first region R1 and the second region R2. The package substrate 100 may further include a fourth region R4 that is spaced apart from the third region R3. The third region R3 may be adjacent to the second side portion S2, and the fourth region R4 may be adjacent to the first side portion S1. As described below, a plurality of second semiconductor chips may be respectively arranged in the third region R3 and the fourth region R4.

A plurality of substrate pads 120 may be arranged at (e.g., in or on) the upper surface 102 of the package substrate 100. Among the plurality of substrate pads 120, first pads may be arranged along an edge region of the first region R1 adjacent to the first region R1. Among the plurality of substrate pads 120, second pads may be arranged along the first side portion S1 and the second side portion S2 of the package substrate 100. Among the plurality of substrate pads 120, third pads may be arranged along the fourth side portion S4 of the package substrate 100. As described below, the first pads may be electrically connected to the first semiconductor chip by conductive connection members such as bonding wires, the second pads may be electrically connected to the plurality of second semiconductor chips by conductive connection members such as bonding wires, and the third pads may be electrically connected to the plurality of third semiconductor chips by conductive connection members such as bonding wires.

The substrate pads 120 may be respectively connected to the wirings. The wirings may extend from the upper surface 102 or within the package substrate 100. For example, at least portions of the wirings may be used as landing pads for the substrate pads. Although only a few substrate pads are illustrated in the figures, it will be understood that the number, shape, and arrangement of the substrate pads are provided for illustration purposes only, and embodiments of the present disclosure are not limited thereto.

As illustrated in FIG. 8, in example embodiments, the package substrate 100 may be a coreless substrate formed by an embedded trace substrate (ETS) method. For example, the package substrate 100 may include a plurality of insulating layers (e.g., a core layer 110a, an upper insulating layer 110b, and a lower insulating layer 110c) and circuit layers (e.g., a circuit layer 112a, a lowermost circuit layer 112b, and an uppermost circuit layer 112c) in the insulating layers. Protective layers (e.g., an upper protective layer 116 and a lower protective layer 118) such as solder resist layers may be formed on outermost surfaces of the circuit layers. An upper protective layer 116 may cover the entire upper surface of the insulating layers except for the substrate pads 120. A lower protective layer 118 may cover the entire lower surface of the insulating layers except for lower substrate pads 130.

Each of the circuit layers may include a wiring pattern. Each of the wiring patterns may include a pad, a trace, a via, etc. An upper surface of the upper protective layer 116 may be provided as the upper surface 102 of the package substrate 100, and a lower surface of the lower protective layer 118 may be provided as the lower surface 104 of the package substrate 100. At least a portion of the pad of the uppermost circuit layer 112c may be provided as the substrate pad 120, and at least a portion of the pad of the lowermost circuit layer 112b may be provided as the lower substrate pad 130. It will be understood that the coreless substrate used as the package substrate is provided as an example, and embodiments of the present disclosure are not limited thereto.

As illustrated in FIGS. 9 to 13, the cavity CA may be formed to have a predetermined depth D from the upper surface 102 of the second region R2 of the package substrate 100.

As illustrated in FIG. 9, for example, a laser processing machine LA may be used to perform laser processing on the upper surface 102 of the second region R2 of the package substrate 100 to form the cavity CA. The cavity CA may be formed by a laser drilling process. A laser in the laser drilling process may include a CO₂ laser, a Yttrium Aluminum Garnet (YAG) laser, an excimer laser, an ultra-violet (UV) laser, etc.

As illustrated in FIG. 13, the cavity CA may have the predetermined depth D from the upper surface 102 of the package substrate 100 and may expose portions (e.g., pad portions such as second substrate pads 122) of the circuit layer 112a in the second region R2. The exposed pad portions may be provided as second substrate pads 122. As described below, a semiconductor element such as a capacitor may be mounted on the second substrate pads 122. The second substrate pads 122 may include a pair of bonding pads (e.g., first bonding pads 122a and second bonding pads 122b) and the pair of first and second bonding pads (e.g., the first bonding pads 122a and the second bonding pads 122b) may be electrically connected to a pair of first and second external terminals of the capacitor, respectively. The predetermined depth D of the cavity CA may be within a range of 100 μm to 200 μm from the upper surface 102 of the package substrate 100. The predetermined depth D of the cavity CA may be determined in consideration of a height of the semiconductor element mounted within the cavity CA, a height of the first semiconductor chip, etc.

As illustrated in FIGS. 10 to 13, a plurality of second substrate pads 122 may be arranged in an array form on a bottom surface of the cavity CA. The plurality of second substrate pads 122 may be provided to mount several to several tens of semiconductor elements. As described below, a plurality of capacitors may be mounted in an array form within the cavity CA.

Referring to FIGS. 14 to 17, a first semiconductor chip 200 may be mounted on the first region R1 of the package substrate 100, and at least one semiconductor element 300 may be mounted in the cavity CA of the package substrate 100.

In example embodiments, the first semiconductor chip 200 may be mounted on the package substrate 100 by a wire bonding method. After attaching the first semiconductor chip 200 on the first region R1 on the upper surface 102 of the package substrate 100 using an adhesive film 220, a wire bonding process may be performed to connect first chip pads 210 of the first semiconductor chip 200 to the substrate pads 120 at (e.g., in or on) the upper surface 102 of the package substrate 100 using bonding wires 230. The first chip pads 210 of the first semiconductor chip 200 may be electrically connected to the substrate pads 120 of the package substrate 100 by the bonding wires 230 as conductive connection members.

The first semiconductor chip 200 may be arranged such that a backside surface 204, opposite to a front surface 202 (e.g., an active surface) at (e.g., in or on) which the first chip pads 210 are formed, faces the package substrate 100. The first semiconductor chip 200 may have a rectangular shape with four sides when viewed in a plan view. For example, a thickness of the first semiconductor chip 200 may be within a range of 90 μm to 150 μm. A height H1 of the first semiconductor chip 200 from the package substrate 100 may be within a range of 125 μm to 200 μm.

Alternatively, the first semiconductor chip 200 may be mounted on the package substrate 100 by a flip chip bonding method. In this case, among the substrate pads 120, the first pads may be arranged in an array form within the first region R1, and the first chip pads 210 of the first semiconductor chip 200 may be electrically connected to the substrate pads 120 of the package substrate 100 via conductive bumps as conductive connection members. For example, the conductive bumps may include micro bumps (uBumps).

The first semiconductor chip 200 may be a logic chip including a logic circuit. The logic chip may be a controller that controls memory chips. The first semiconductor chip may be a processor chip such as an ASIC or an application processor (AP) as a host such as a CPU, GPU, or SOC.

Then, a plurality of semiconductor elements 300 may be placed in the cavity CA of the package substrate 100. The semiconductor elements 300 may be electrically connected to the first semiconductor chip 200 to remove electrical noises and ensure that power is supplied uniformly. For example, the number of the semiconductor elements 300 may be within a range of 6 to 15.

For example, the semiconductor elements 300 may include a passive device, a multi-layer ceramic capacitor (MLCC), a low inductance chip capacitor (LICC), a die side capacitor (DSC), a land side capacitor (LSC), an inductor, an integrated passive device (IPD), etc.

The plurality of semiconductor elements 300 may be mounted on the second substrate pads 122 of the package substrate 100 via conductive bumps 320. After the conductive bumps 320 are formed on the first external terminal 310a and the second external terminal 310b of the semiconductor elements 300, the conductive bumps 320 may be bonded to the pair of bonding pads (e.g., the first bonding pad 122a and the second bonding pad 122b) of the second substrate pads 122 by a reflow process. Accordingly, the first external terminal 310a and the second exterminable terminal 310b of the semiconductor element 300 may be electrically connected to the second substrate pads 122 (i.e., the first bonding pad 122a and the second bonding pad 122b) of the package substrate 100 via the conductive bumps 320 as conductive connection members.

A length of the semiconductor element 300 in the first direction (X direction), that is, a width W may be within a range of 100 μm to 250 μm. A length L of the semiconductor element 300 in the second direction (Y direction) may be within a range of 200 μm to 600 μm. A height H1 of the semiconductor element 300 may be within a range of 250 μm to 400 μm. The semiconductor element 300 may protrude from the package substrate 100 by a predetermined height H3. The semiconductor elements 300 may protrude from the package substrate 100 to be used as support spacers to support at least a portion of the second semiconductor chip 500. The height H3 of the semiconductor element 300 protruding from the package substrate 100 may be determined in consideration of the height H1 of the first semiconductor chip 200 from the package substrate 100. The height H3 of the semiconductor element 300 protruding from the package substrate 100 may be equal to or greater than the height H1 of the first semiconductor chip 200 from the package substrate 100.

Referring to FIGS. 18 to 22, a plurality of second semiconductor chips 500 may be attached onto the at least one semiconductor element 300 using adhesive films 520.

As illustrated in FIGS. 18 to 20, a lowermost second semiconductor chip 500a may be attached onto the plurality of semiconductor elements 300 using a first adhesive film 520a. The lowermost second semiconductor chip 500a may be attached onto the plurality of semiconductor elements 300 and the first semiconductor chip 200 using a first adhesive film 520a such as a die attach film (DAF) by a die attach process. The lowermost second semiconductor chip 500a may be placed on the third region R3.

The lowermost second semiconductor chip 500a may be arranged such that a backside surface (i.e., an inactive surface), which is opposite to a front surface where second chip pads 510a are formed, faces the package substrate 100. The lowermost second semiconductor chip 500a may have a rectangular shape having four sides when viewed in a plan view.

The second semiconductor chips 500 may include a memory chip including a memory circuit. For example, the second semiconductor chips 500 may include volatile memory devices such as SRAM devices, DRAM devices, etc., and non-volatile memory devices such as flash memory devices, PRAM devices, MRAM devices, ReRAM devices, etc. In this embodiment, the second semiconductor chip may include DRAM devices.

For example, a first adhesive film 520a may be attached to the backside surface of the lowermost second semiconductor chip 500a, and the lowermost second semiconductor chip 500a to which the first adhesive film 520a is attached may be attached to the plurality of semiconductor elements 300 and the first semiconductor chip 200 by a thermal compression process. The lowermost second semiconductor chip 500a may be pressed onto the plurality of semiconductor elements 300 by a die attaching tool, and may be heated to a high temperature by a heater block within a support system that supports the package substrate 100. Due to the pressure and temperature, a portion of the DAF having fluidity may flow into a space between the first semiconductor chip 200 and the plurality of semiconductor elements 300 and fill the inside of the cavity CA. A portion of the DAF inside the cavity CA may fill a space between the semiconductor elements 300 and a sidewall of the cavity CA and a space between the semiconductor elements 300 and the bottom surface of the cavity CA.

In example embodiments, a spacer chip 400 may be attached on the fourth region R4 of the package substrate 100, and the lowermost second semiconductor chip 500a may be attached on the spacer chip 400.

The spacer chip 400 may be placed on the fourth region R4 spaced apart from the third region R3. The spacer chip 400 may be formed by cutting a silicon wafer by a sawing process, and then may be attached on the upper surface 102 of the package substrate 100 using an adhesive film by a die attach process. A height of the spacer chip 400 from the package substrate 100 may be equal to or similar to the height H3 of the first semiconductor chip 200.

The lowermost second semiconductor chip 500a may be attached onto the spacer chip 400 using the first adhesive film 520a. The lowermost second semiconductor chip 500a may be attached onto the spacer chip 400 using the first adhesive film 520a such as a die attach film (DAF) by a die attach process. A planar area of the lowermost second semiconductor chip 500a may be the same as or similar to a planar area of the spacer chip 400.

Then, the lowermost second semiconductor chip 500a may be electrically connected to the package substrate 100 by conductive connection members (e.g., bonding wires 530).

In example embodiments, a wire bonding process may be performed to connect second chip pads 510a of the lowermost second semiconductor chip 500a to the substrate pads 120 on the upper surface 102 of the package substrate 100 by bonding wires 530.

Then, as illustrated in FIGS. 22 and 23, a remaining chip (e.g., the second semiconductor chip 500b) among the plurality of second semiconductor chips 500 may be sequentially attached onto the lowermost second semiconductor chip 500a using a second adhesive film 520b. The second semiconductor chip 500b may be sequentially attached onto the lowermost second semiconductor chip 500a using the second adhesive film 520b such as a die attach film (DAF) by a die attach process. A thickness of the second adhesive film 520b may be less than a thickness of the first adhesive film 520a. The thickness of the second adhesive film 520b may be within a range of 10 μm to 20 μm.

A planar area of the second semiconductor chip 500 (e.g., the second semiconductor chip 500b) may be greater than a planar area of the first semiconductor chip 200. Accordingly, the plurality of second semiconductor chips 500 may be supported and mounted on the third region R3 of the package substrate 100 by the plurality of semiconductor elements 300. The plurality of second semiconductor chips 500 may be supported and mounted on the fourth region R4 of the package substrate 100 by the spacer chip 400.

The plurality of second semiconductor chips 500 may be aligned to overlap each other. Alternatively, the plurality of second semiconductor chips 500 may be offset aligned from each other.

It will be understood that the number, size, arrangement, etc., of the second semiconductor chips 500 are provided as examples, and embodiments of the present disclosure are not limited thereto. Additionally, although only a few second chip pads 510 are illustrated in the figures, it will be understood that the structure, shape and arrangement of the second chip pads 510 are provided by way of example, and that embodiments of the present disclosure are not limited thereto.

Then, the second semiconductor chip 500b may be electrically connected to the package substrate 100 by conductive connection members (e.g., bonding wires 530).

In example embodiments, a wire bonding process may be performed to connect second chip pads 510b of the second semiconductor chip 500b to the substrate pads 120 at (e.g., in or on) the upper surface 102 of the package substrate 100 by the bonding wires 530.

Referring to FIGS. 23 to 25, a plurality of third semiconductor chips 600 may be attached onto the plurality of third semiconductor chips 600 by using adhesive films 620.

In example embodiments, a lowermost third semiconductor chip 600a may be attached onto the plurality of second semiconductor chips 500 by using a third adhesive film 620a. The lowermost third semiconductor chip 600a may be attached onto the plurality of second semiconductor chips 500 by using a third adhesive film 620a such as a die attach film (DAF) by a die attach process. The lowermost third semiconductor chip 600a may be placed on the plurality of second semiconductor chips 500 on the third region R3 and the plurality of second semiconductor chips 500 on the fourth region R4. The lowermost third semiconductor chip 600a may have a rectangular shape extending in the first direction (X direction) to cover the third region R3 and the fourth region R4 that are spaced apart from each other. The lowermost third semiconductor chip 600a may be arranged such that a backside surface (e.g., an inactive surface), which is opposite to a front surface where the third chip pads 610a are formed, faces the package substrate 100.

The third semiconductor chips 600 may include a memory chip including a memory circuit. For example, the third semiconductor chips 600 may include volatile memory devices such as SRAM devices, DRAM devices, and non-volatile memory devices such as flash memory devices, PRAM devices, MRAM devices, ReRAM devices, etc. In this embodiment, the third semiconductor chips 600 may include VNAND devices.

For example, the third adhesive film 620a may be attached to the backside surface of the lowermost third semiconductor chip 600a, and the lowermost third semiconductor chip 600a to which the third adhesive film 620a is attached may be attached to the plurality of second semiconductor chips 500 by a thermal compression process.

Then, a remaining chip (e.g., the third semiconductor chip 600b) among the plurality of third semiconductor chips 600 may be sequentially attached onto the lowermost third semiconductor chip 600a using a fourth adhesive film 620b. The third semiconductor chip 600b may be sequentially attached onto the lowermost third semiconductor chip 600a using the fourth adhesive film 620b such as a die attach film (DAF) by a die attach process.

The plurality of third semiconductor chips 600 may be sequentially offset aligned from each other. For example, the third semiconductor chips 600 may be stacked in a cascade structure. The third semiconductor chips 600 may be sequentially offset aligned in a third side direction (Y direction) of the package substrate 100. Alternatively, the plurality of third semiconductor chips 600 may be stacked to overlap each other.

Then, the third semiconductor chips 600 may be electrically connected to the package substrate 100 by conductive connection members (e.g., bonding wires 630).

In example embodiments, a wire bonding process may be performed to connect the third chip pads 610a, 610b of the third semiconductor chips 600 to the substrate pads 120 at (e.g., in or on) the upper surface 102 of the package substrate 100 by bonding wires 630.

It will be understood that the number, size, arrangement, etc., of the third semiconductor chips 600 are provided as examples, and embodiments of the present disclosure are not limited thereto. Additionally, although only a few third chip pads 610 are illustrated in the figures, it will be understood that the structure, shapes and arrangements of the third chip pads 610 are provided by way of example, and that embodiments of the present disclosure are not limited thereto.

Then, a molding member 700 (see FIGS. 2 and 3) may be formed on the upper surface 102 of the package substrate 100 to cover the plurality of second semiconductor chips 500, the plurality of third semiconductor chips 600, and the bonding wires 230, 530, 630. The molding member may include a thermosetting resin such as, for example, an epoxy mold compound (EMC).

Then, external connection members may be formed on the lower substrate pads 130 on the lower surface 104 of the package substrate 100, to complete the semiconductor package 10 of FIG. 1.

For example, the external connection members may include solder balls. The external connection members may be formed on the lower substrate pads 130 at the lower surface 104 of the package substrate 100 respectively by a solder ball attach process.

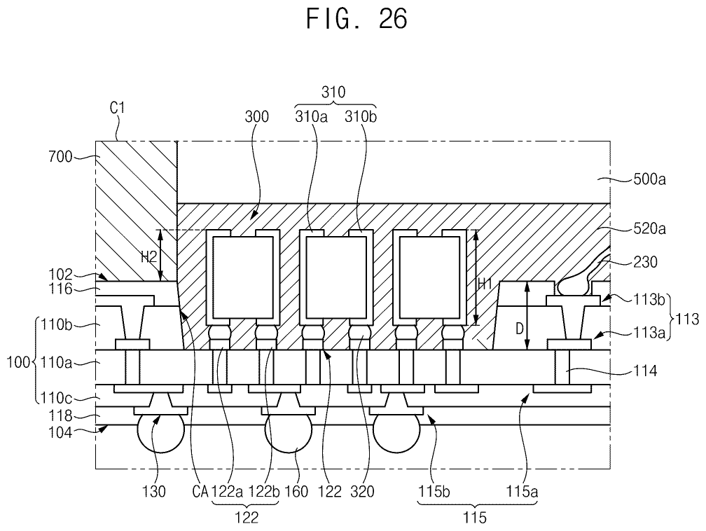

FIG. 26 is an enlarged cross-sectional view illustrating a portion of a semiconductor package in accordance with example embodiments. FIG. 26 is an enlarged cross-sectional view illustrating the portion C1 in FIG. 2. The semiconductor package may be substantially the same as or similar to the semiconductor package described with reference to FIGS. 1 to 4 except for a configuration of the package substrate. Thus, same reference numerals will be used to refer to the same or like elements and any further repetitive explanation concerning the above elements may be omitted.

Referring to FIG. 26, a package substrate 100 of a semiconductor package may include a core multilayer substrate.

In example embodiments, the package substrate 100 may include a core layer 110a, an upper insulating layer 110b on an upper surface of the core layer 110a, and a lower insulating layer 110c on a lower surface of the core layer 110a. The package substrate 100 may further include a plurality of through vias 114 penetrating the core layer 110a, a first upper circuit layer 113a on the upper surface of the core layer 110a, a second upper circuit layer 113b provided on the upper insulating layer 110b, a first lower circuit layer 115a on the lower surface of the core layer 110a, and a second lower circuit layer 115b provided on the lower insulating layer 110c. Protective layers (e.g., an upper protective layer 116 and a lower protective layer 118) such as solder resist layers may be formed on outermost surfaces of the circuit layers. An upper protective layer 116 may cover the entire upper surface of the insulating layers except for substrate pads 120. A lower protective layer 118 may cover the entire lower surface of the insulating layer except for lower substrate pads 130.

Each of the circuit layers may include a wiring pattern. Each of the wiring patterns may include a pad, a trace, a via, etc. An upper surface of the upper protective layer 116 may be provided as an upper surface 102 of the package substrate 100, and a lower surface of the lower protective layer 118 may be provided as a lower surface 104 of the package substrate 100. At least a portion of a pad of the second upper circuit layer 113b may be provided as the substrate pad 120, and at least a portion of a pad of the second lower circuit layer 115b may be provided as the lower substrate pad 130.

A cavity CA may be provided to have a predetermined depth D from the upper surface 102 of a second region R2 of the package substrate 100. For example, the cavity CA may be formed by a laser drilling process. The cavity CA may have the predetermined depth D from the upper surface 102 of the package substrate 100 and may expose portions (e.g., pad portions such as second substrate pads 122) of the first upper circuit layer 113a in the second region R2. The exposed pad portions can be provided as second substrate pads 122.

A semiconductor element 300 such as a capacitor may be mounted on the second substrate pads 122 of the package substrate 100 via conductive bumps 320. The conductive bumps 320 may be bonded to a first external terminal 310a and a second external connection terminal 310b of the semiconductor element 300 and a pair of bonding pads (e.g., the first bonding pad 122a and the second bonding pad 122b) of the second substrate pads 122. Accordingly, the first external terminal 310a and the second external terminal 310b of the semiconductor element 300 may be electrically connected to the second substrate pads 122 (e.g., the first bonding pad 122a and the second bonding pad 122b) of the package substrate 100 by the conductive bumps 320 as conductive connection members.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, high bandwidth memory (HBM) devices, or non-volatile memory devices such as flash memory devices, PRAM devices, MRAM devices, RRAM devices, or the like.

The foregoing is illustrative of non-limiting example embodiments of the present disclosure and is not to be construed as limiting the present disclosure. Although a few non-limiting example embodiments of the present disclosure have been described, those skilled in the art will readily appreciate that many modifications are possible in example embodiments of the present disclosure without departing from the spirit and scope of the present disclosure. Accordingly, all such modifications are intended to be included within the scope of the present disclosure.

What is claimed is:

1. A semiconductor package, comprising:
a package substrate comprising a first region and a second region adjacent to the first region, the package substrate further comprising a cavity that is recessed from an upper surface of the package substrate in the second region;
a first semiconductor chip on the upper surface of the package substrate, wherein the first semiconductor chip is on the first region of the package substrate;
at least one semiconductor element in the cavity of the package substrate, the at least one semiconductor element protruding above the upper surface of the package substrate;
a plurality of second semiconductor chips sequentially stacked on the at least one semiconductor element and overlapping with the first semiconductor chip, wherein the plurality of second semiconductor chips are connected to each other and the first semiconductor chip by adhesive films; and
a molding member on the plurality of second semiconductor chips and the package substrate.

2. The semiconductor package of claim 1, wherein a lowermost second semiconductor chip among the plurality of second semiconductor chips is attached to the at least one semiconductor element by a first adhesive film among the adhesive films, and
wherein a portion of the first adhesive film fills an inside of the cavity of the package substrate.

3. The semiconductor package of claim 2, wherein another second semiconductor chip among the plurality of second semiconductor chips is attached to the lowermost second semiconductor chip by a second adhesive film among the adhesive films.

4. The semiconductor package of claim 2, wherein the first adhesive film fills a space between the first semiconductor chip and the at least one semiconductor element.

5. The semiconductor package of claim 2, wherein the at least one semiconductor element has a thickness within a range of 250 μm to 400 μm, and a depth of the cavity is within a range of 100 μm to 200 μm.

6. The semiconductor package of claim 1, wherein the adhesive films comprise a die attach film.

7. The semiconductor package of claim 1, further comprising:
a first bonding wire electrically connecting a first chip pad of the first semiconductor chip to a first substrate pad of the package substrate.

8. The semiconductor package of claim 1, wherein the at least one semiconductor element is connected to the package substrate by a conductive bump that is on a substrate pad, and
wherein the substrate pad is at a bottom surface of the cavity.

9. The semiconductor package of claim 1, wherein the at least one semiconductor element comprises at least one from among a passive device, a multilayer ceramic capacitor (MLCC), a low inductance chip capacitor (LICC), a die side capacitor (DSC), a land side capacitor (LSC), an inductor, and an integrated passive device (IPD).

10. The semiconductor package of claim 1, further comprising:
a spacer chip on the package substrate and horizontally spaced apart from the first region and the second region; and
a plurality of third semiconductor chips sequentially stacked on the spacer chip, wherein the plurality of third semiconductor chips are connected to each other and the spacer chip by additional adhesive films.

11. A semiconductor package, comprising:
a package substrate comprising a first region and a second region adjacent to the first region, the package substrate further comprising a cavity in the second region, in an upper surface of the package substrate;
a first semiconductor chip on the upper surface of the package substrate, wherein the first semiconductor chip is on the first region of the package substrate;
at least one semiconductor element in the cavity of the package substrate, the at least one semiconductor element protruding above the upper surface of the package substrate;
a first adhesive film on the at least one semiconductor element and the first semiconductor chip, and in the cavity;
a plurality of second semiconductor chips sequentially stacked on the first adhesive film;
bonding wires electrically connecting the plurality of second semiconductor chips to the package substrate; and
a molding member on the plurality of second semiconductor chips and the package substrate.

12. The semiconductor package of claim 11, wherein a lowermost second semiconductor chip among the plurality of second semiconductor chips is attached to the at least one semiconductor element by the first adhesive film, and another second semiconductor chip among the plurality of second semiconductor chips is attached to the lowermost second semiconductor chip by a second adhesive film.

13. The semiconductor package of claim 11, wherein the first adhesive film is in a space between the first semiconductor chip and the at least one semiconductor element.

14. The semiconductor package of claim 11, wherein the at least one semiconductor element has a thickness within a range of 250 μm to 400 μm, and a depth of the cavity is within a range of 100 μm to 200 μm.

15. The semiconductor package of claim 11, wherein the first adhesive film comprises a die attach film.

16. The semiconductor package of claim 11, further comprising:
a first bonding wire electrically connecting a first chip pad of the first semiconductor chip to a first substrate pad of the package substrate.

17. The semiconductor package of claim 11, wherein the at least one semiconductor element is connected to the package substrate by a conductive bump that is on a substrate pad, and
wherein the substrate pad is at a bottom surface of the cavity.

18. The semiconductor package of claim 11, wherein the at least one semiconductor element comprises at least one from among a passive device, a multilayer ceramic capacitor (MLCC), a low inductance chip capacitor (LICC), a die side capacitor (DSC), a land side capacitor (LSC), an inductor, and an integrated passive device (IPD).

19. The semiconductor package of claim 11, further comprising:
a spacer chip on the package substrate and horizontally spaced apart from the first region and the second region; and
a plurality of third semiconductor chips sequentially stacked on the spacer chip, wherein the plurality of third semiconductor chips are connected to each other and the spacer chip by second adhesive films.

20. A semiconductor package, comprising:
a package substrate comprising a third region and a fourth region spaced apart from the third region, the third region comprising a first region and a second region, and the package substrate further comprising a cavity in the second region, in an upper surface of the package substrate;
a first semiconductor chip on the first region, on the upper surface of the package substrate;
at least one semiconductor element in the cavity, the at least one semiconductor element protruding from the upper surface of the package substrate;
a plurality of second semiconductor chips on the third region, on the upper surface of the package substrate, and sequentially stacked on the at least one semiconductor element, wherein the plurality of second semiconductor chips are connected to each other and the first semiconductor chip by first adhesive films;
a spacer chip on the fourth region, on the upper surface of the package substrate;
a plurality of third semiconductor chips sequentially stacked on the spacer chip, wherein the plurality of third semiconductor chips are connected to each other and the spacer chip by second adhesive films;
a plurality of fourth semiconductor chips sequentially stacked on the plurality of second semiconductor chips and the plurality of third semiconductor chips, wherein the plurality of fourth semiconductor chips are connected to each other and the plurality of second semiconductor chips and the plurality of third semiconductor chips by third adhesive films; and
a molding member on the plurality of second semiconductor chips, the plurality of third semiconductor chips, the plurality of fourth semiconductor chips, and the package substrate.
